(19) United States
(12) Patent Application Publication
(10) Pub. No.: US 2026/0304852 A1
(43) Pub. Date: Oct. 1, 2026

(54) METHOD FOR FORMING A SUPERJUNCTION DEVICE AND SUPERJUNCTION DEVICE

(71) Applicant: Infineon Technologies Austria AG, Villach (AT)

(72) Inventors: Christian Fachmann, Villach (AT); Franz Hirler, Isen (DE); Maximilian Treiber, München (DE); Armin Willmeroth, Friedberg (DE); Feng Yu, Unterhaching (DE); Ingo Muri, Villach (AT); Dan Horia Popescu, München (DE)

(21) Appl. No.: 19/629,798

(22) Filed: Mar. 26, 2026

(30) Foreign Application Priority Data
Mar. 28, 2025 (DE) 102025112318.7

(51) Int. Cl. H10D 62/00; H10D 30/66; H10D 62/10

(52) U.S. Cl. CPC H10D 62/054; H10D 30/668; H10D 62/111

(57) ABSTRACT

A method for forming a superjunction device and a superjunction device are disclosed. The method includes: forming a superjunction region including first regions of a first doping type and second regions of a complementary second doping type; forming semiconductor layers one above the other to form a layer stack; implanting first type dopant atoms through openings of a first implantation mask in each of the semiconductor layers to form first implanted regions; implanting second type dopant atoms through openings of a second implantation mask in each of the semiconductor layers to form second implanted regions; and an annealing process to diffuse and activate the implanted first type dopant atoms and second type dopant atoms. Both implantation masks have a pitch selected from between 3 micrometers and 5 micrometers. Each of the semiconductor layers has a thickness selected from between 1.9 micrometers and 3.5 micrometers.

### TECHNICAL FIELD

This disclosure relates in general to a superjunction device, in particular a vertical superjunction transistor device, and a method for producing thereof.

### BACKGROUND

A superjunction transistor device includes a plurality of transistor cells and a superjunction region with a plurality of first regions of a first doping type and a plurality of second regions of a second doping type complementary to the first doping type. The first region may also be referred to as the drift regions and the second regions may also be referred to as compensation regions. The first regions (drift regions) are coupled to a drain node and the second regions (compensation regions) are coupled a source node of the transistor device.

The transistor device can be operated in an on-state or an off-state. In the on-state, a current can flow from the source node through the transistor cells and the first regions of the superjunction region to the drain node. In the off-state, space charge regions (depletion regions) expand in the first and second regions of the superjunction region and cause the superjunction region to be depleted of charge so that a current flow between the source region and the drain region is interrupted.

The on-resistance is the electrical resistance of the transistor device between the source node and the drain node in the on-state. The on-resistance is mainly determined by an electrical resistance of the first regions in the superjunction region. The on-resistance causes power losses in circuit applications that include the transistor device, such as power converters, motor drives, or the like. Such power losses are undesirable.

There is therefore a need for a superjunction device, in particular a superjunction transistor device with a reduced on-resistance.

### SUMMARY

One example relates to a method for forming a superjunction device. The method includes: forming a superjunction region, the superjunction region including a plurality of first regions of a first doping type and a plurality of second regions of a second doping type complementary to the first doping type. Forming the superjunction region includes: forming a plurality of semiconductor layers one above the other to form a layer stack; implanting first type dopant atoms through openings of a first implantation mask in each of the semiconductor layers to form first implanted regions; implanting second type dopant atoms through openings of a second implantation mask in each of the semiconductor layers to form second implanted regions; and an annealing process to diffuse and activate the implanted first type dopant atoms and second type dopant atoms. Each of the first implantation mask and the second implantation mask has a pitch selected from between 3 micrometers and 5 micrometers, and each of the semiconductor layers has a thickness selected from between 1.9 micrometers and 3.5 micrometers.

Another example relates to a superjunction device. The superjunction device includes: a superjunction region including a plurality of first regions of a first doping type and a plurality of second regions of a second doping type complementary to the first doping type in a layer stack including a plurality of semiconductor layers formed one above the other to form a layer stack. The pitch of the superjunction region is selected from between 3 micrometers and 5 micrometers, and each of the semiconductor layers has a thickness selected from between 1.9 micrometers and 3.5 micrometers.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of a superjunction transistor device including transistor cells and a superjunction region;

FIG. 2 schematically illustrates a horizontal cross-sectional view of the superjunction region according to one example;

FIG. 3 illustrate one example of a method for forming the superjunction region, the method including forming a plurality of semiconductor layers one above the other and implanting first type dopant atoms and second type dopant atoms into each of the semiconductor layers;

FIGS. 4A-4B illustrates in detail one example of a method for implanting first type dopant atoms and second type dopant atoms into one of the semiconductor layers;

FIG. 5 illustrates the arrangement shown in FIG. 3 after forming another semiconductor layer;

FIGS. 6A-6B each illustrate an electric field in a pair of neighboring first and second regions of the superjunction region in the off-state of the transistor device;

FIG. 7 illustrates the doping profile of one first region or one second region according to one example;

FIG. 8 illustrates the dependency of a specific on-resistance (Ron.A) of the transistor device on a pitch of the superjunction region;

FIGS. 9A-9B illustrate a modification of the method illustrated in FIGS. 4A-4B;

FIG. 10 illustrates an annealing process in an oxidizing ambient during a manufacturing process according to one example;

FIGS. 11A-11C illustrate examples of dopant doses introduced into each of the semiconductor layers dependent on a position of the semiconductor layer in a layer stack formed by the semiconductor layers;

FIG. 12 schematically illustrates a vertical cross-sectional view of several transistor cells according to one example;

FIG. 13 schematically illustrates a horizontal cross-sectional view of the transistor cells according to FIG. 11; and

FIGS. 14-15 illustrate top views of a transistor device according to different examples.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

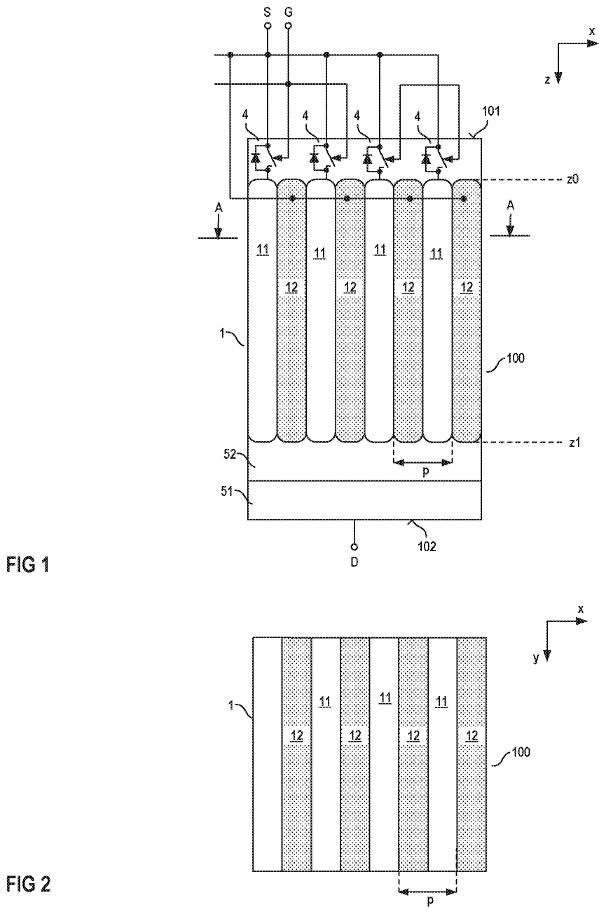

FIG. 1 schematically illustrates a superjunction transistor device according to one example. More specifically, FIG. 1 schematically illustrates a vertical cross-sectional view of a part of the transistor device. The transistor device includes a semiconductor body 100 with a first surface 101 and a second surface 102 opposite the first surface. FIG. 1 illustrates a vertical cross-sectional view of the semiconductor body 100 in a vertical section plane which is substantially perpendicular to the first and second surfaces 101, 102.

According to one example, the semiconductor body 100 includes a monocrystalline semiconductor material. The monocrystalline semiconductor material is silicon (Si) or silicon carbide (SiC), for example.

The semiconductor body 100 further includes a first lateral direction x and a second lateral direction y, the second lateral direction y being substantially perpendicular to the first lateral direction x. The first and second lateral directions are substantially parallel to the first and second surfaces 101, 102 and perpendicular to the vertical direction z. With regard to the first lateral direction x it should be noted that, unless stated otherwise, “first lateral direction x” includes both the direction as indicated by the arrow labelled with x in the figures and the opposite direction. The same applies to the second lateral direction y, which includes both the direction as indicated by the arrow labelled with y in the figures and the opposite direction, and the vertical direction z, which includes both the direction as indicated by the arrow labelled with z in the figures and the opposite direction.

Referring to FIG. 1, the superjunction transistor device includes a superjunction region 1. The superjunction region 1 includes first regions 11 of a first doping type and second regions 12 of a second doping type complementary to the first doping type. The first regions 11 and the second regions 12 are arranged alternately in the first lateral direction x of the semiconductor body 100. The first regions 11 of the superjunction region 1 may also be referred to as a drift regions and the second regions 12 may also be referred to as compensation regions. It goes without saying that a doped region of a first doping type as used herein is a doped region having an effective doping concentration of the first doping type, and a doped region of a second doping type as used herein is a doped region having an effective doping concentration of the second doping type.

According to one example illustrated in FIG. 2, the first and second regions 11, 12 are elongated in the second lateral direction y. FIG. 2 schematically illustrates a horizontal cross-sectional view of the transistor device of the type illustrated in FIG. 1 in a horizontal sectional plane A-A intersecting the superjunction region 1 with the first and second regions 11, 12. Elongated as used herein includes that a length of the first and second regions 11, 12 is much larger than a respective width of the first and second regions 11, 12. According to one example, the length is at least 50 times, at least 100 times, or at least 500 times the width. The length is the dimension of the first and second regions 11, 12 in the second lateral direction y. The width is the dimension of the first and second regions 11, 12 in the first lateral direction x. Furthermore, the first and second regions 11, 12 are not necessarily contiguous in the second lateral direction y, but each of the first and second regions 11, 12 may include one or more elongated sections arranged spaced apart from each other in the second lateral direction y.

Referring to FIG. 1, the transistor device further includes a drain region 51 of the first doping type. The drain region 51 is arranged between the superjunction region 1 and the second surface 102 and may adjoin the second surface 102. The drain region 51 forms a drain node D or is connected to a drain node D of the transistor device.

According to one example, as illustrated in FIG. 1, the drain region 51 is spaced apart from the superjunction region 1 in the vertical direction z. In this example, a buffer region 52 of the first doping type is arranged between the drain region 51 and the superjunction region 1. A doping concentration of the buffer region 52 is lower than a doping concentration of the drain region 51, such as more than two orders of magnitude lower than the doping concentration of the drain region 51.

The doping concentration of the drain region 51 is in a range of between 5E18 cm⁻³ and 5E20 cm⁻³ and the doping concentration of the buffer region 52 is in a range of between 3E15 cm⁻³ and 3E16 cm⁻³, for example.

The drain region 51 and the optional buffer region 52 couple (connect) the first regions 11 of the superjunction region 1 to the drain node D of the transistor device.

Referring to FIG. 1, the transistor device further includes transistor cells 4 that are at least partially integrated in the semiconductor body 100. “At least partially integrated” includes that at least active device regions, such as source and body regions (explained herein further below) are integrated in the semiconductor body 100. Each transistor cell 4 is coupled between a source node S of the transistor device and at least one of the first regions 11 of the superjunction region 1. Furthermore, each transistor cell 4 is configured to control a conducting channel between the source node S and the respective first region 11. The transistor cells 4 are not illustrated in detail in FIG. 1. Instead, in FIG. 1, each of the transistor cells 2 is represented by a controllable electronic switch with a parallel diode, which symbolize the functionality of the transistor cells. A detailed example of the transistor cells 4 is explained herein further below.

The transistor device illustrated in FIG. 1 can be operated in a forward biased mode (forward biased state) or a reverse biased mode (reverse biased estate). The reverse biased mode may also be referred to as diode mode of the transistor device. The transistor device is in the reverse biased mode when a polarity of a voltage applied between the drain node D and the source node S is such that the diodes in the transistor cells 4 are forward biased; and the transistor device is in the forward biased mode when the polarity of the voltage applied between the drain node D and the source node S is such that the diodes in the transistor cells 4 are reverse biased. In the forward biased mode, the transistor device can be operated in an on-state or an off-state. The transistor device is in the on-state when there are conducting channels in the transistor cells 4 between the source node S and the first regions 11 of the first superjunction region 1; and the transistor device is in the off-state when the conducting channels are interrupted.

According to one example, the transistor device is a gate-controlled transistor device. In this example, the presence of conducting channels in the transistor cells 4 is dependent on a voltage (gate-source voltage) applied between a gate node G and the source node S, so that the transistor device is in the on-state or the off-state dependent on the gate-source voltage.

The second regions 12 of the superjunction region 1 are coupled to the source node S. This coupling of the second regions 12 to the source node S is only schematically illustrated in FIG. 1. According to one example, the second regions 12 are coupled to the source node S via the transistor cells 4. One example of coupling the second regions 12 to the source node S is explained herein further below. Furthermore, the first regions 11 of the first superjunction region 1 are coupled to the drain region 51 and the drain node D. The first regions 11 are coupled to the drain region 51 either directly by adjoining the drain region 51, or through the buffer region 52.

When the transistor device is in the off-state and a voltage is applied between the drain node D and the source node S space, charge regions (depletion regions) expand in the first regions 11 and the second regions 12 beginning at PN junctions formed between adjacent first and second regions 11, 12. This enables the first superjunction region 1 to substantially absorb the voltage applied between the drain node D and the source node S of the transistor device. This is a well-known operating principle of superjunction devices, so that no further explanation is required in this regard.

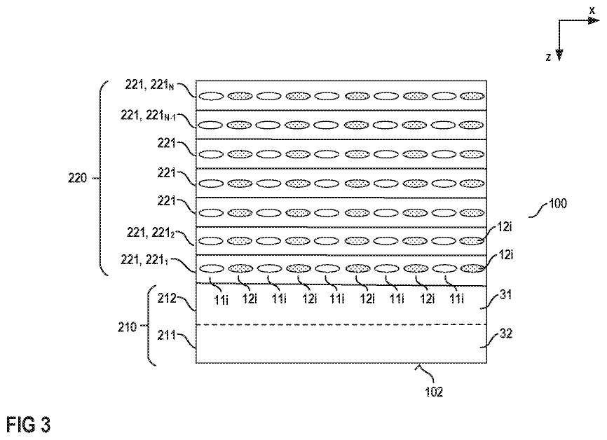

According to one example, forming the first and second superjunction regions 1, 2 includes forming a plurality of semiconductor layers one above the other and implanting first type dopant atoms and second type dopant atoms in each of the semiconductor layers. The semiconductor layers are epitaxially grown layers (epitaxial layers) according to one example, so that this type of process is sometimes referred to as multi-epi-multi-implant (MEMI) process. A part of the method for forming the first and second regions 11, 12 using an MEMI process is illustrated in FIG. 3.

FIG. 3 shows a vertical cross-sectional view of a portion of the semiconductor body 100 after forming several semiconductor layers 221 one above the other on top of a carrier 210, and implanting first type dopant atoms and second type dopant atoms into each of the semiconductor layers 221. The first and second type dopant atoms included in a respective one of the semiconductor layers 221 are implanted into the semiconductor layer 221 before the next semiconductor layer 221 is formed (grown).

The semiconductor layers 221 formed above one above the other form a layer stack 220 on top of the carrier 210. The layer stack includes a lowermost semiconductor layer 221₁, which is the semiconductor layer 221 of the layer stack 220 that is produced first, and an uppermost semiconductor layer 221_{N}, which is the semiconductor layer 221 of the layer stack 220 that is produced last in the manufacturing process. The lowermost semiconductor layer 221₁ is produced directly on top of the carrier 210.

According to one example, the carrier 210 includes a semiconductor substrate 211 forming the drain region 51 in the finished device and an epitaxial layer 212 grown on top of the substrate 211 and forming the buffer region 52 in the finished device. The epitaxial layer forming the buffer region may be in-situ doped during the epitaxial growth process.

Referring to FIG. 3, implanting the first type dopant atoms into each of the semiconductor layers 220 forms first implanted regions 11i, and implanting the second type dopant atoms into each of the semiconductor layers 221 forms second implanted regions 12i. Referring to FIG. 3 lateral positions of the first implanted regions 11i in the semiconductor layers 221 are selected such that the plurality of first implanted regions 11i form a plurality of groups, each group including one first implanted region 11i in each semiconductor layer 221, and the first implanted regions 11i of each group being arranged one above the other in the vertical direction z. In a similar way, lateral positions of the second implanted regions 12i in the semiconductor layers 221 are selected such that the plurality of second implanted regions 12i form a plurality of groups, each group including one second implanted region 12i in each semiconductor layer 221, and the second implanted regions 12i of each group being arranged one above the other in the vertical direction z.

According to one example, the first and second implanted regions 11i, 12i formed in each of the semiconductor layers 221 do not overlap. According to one example, the first and second implanted regions 11i, 12i formed in each of the semiconductor layers are spaced apart from each other in the first lateral direction x.

It should be noted that the implantation processes explained above may take place at wafer level. That is, the implantation processes may take place when a plurality of semiconductor bodies are part of a wafer which is eventually diced to form the individual semiconductor bodies.

In order to form the first and second regions 11, 12 based on the first and second implanted regions 11i, 12i, the method further includes a temperature process (annealing process) that causes the implanted first and second type dopant atoms to diffuse and to be electrically activated.

Implanting the first and second type dopant atoms in the semiconductor layers 221 to form the first and second implanted regions 11i, 12i may include adjusting an implantation energy in the implantation processes such that the first and second type dopant atoms are implanted only into one of the second semiconductor layers 221, 222, namely that one of the semiconductor layers 221 that was produced last before the respective implantation process. As can be seen from FIG. 3, first implanted regions 11i formed one above the other in the vertical direction z may be spaced apart from each other and second implanted regions 12i formed one above the other in the vertical direction z may be spaced apart from each other. In this case, in order to form contiguous first regions 11 and contiguous second regions 12 in the vertical direction z, a diffusion of the implanted first and second type dopant atoms in the vertical direction z in the annealing process is desired. The temperature and the duration of the annealing process are selected such that the desired vertical diffusion of the first and second type dopant atoms is achieved.

It should be noted that the semiconductor body 100 with the carrier 210 and the layer stack 220 with the semiconductor layers 221 is a monocrystalline semiconductor body 100. That is, a border between the carrier 210 and the layer stack 220 and between the individual semiconductor layers 221 in the layer stack 220 is not visible. In FIG. 3, borders between the individual semiconductor layers 221 are only shown for illustration purposes.

The semiconductor layers 221 may be produced (grown) to have a low basic doping concentration before the first and second implanted regions 11i, 12i are formed by implanting first and second type dopant atoms. According to one example, the basic doping concentration is lower than 1E14 cm⁻³ or lower than 1E13 cm⁻³ and may be as low as intrinsic.

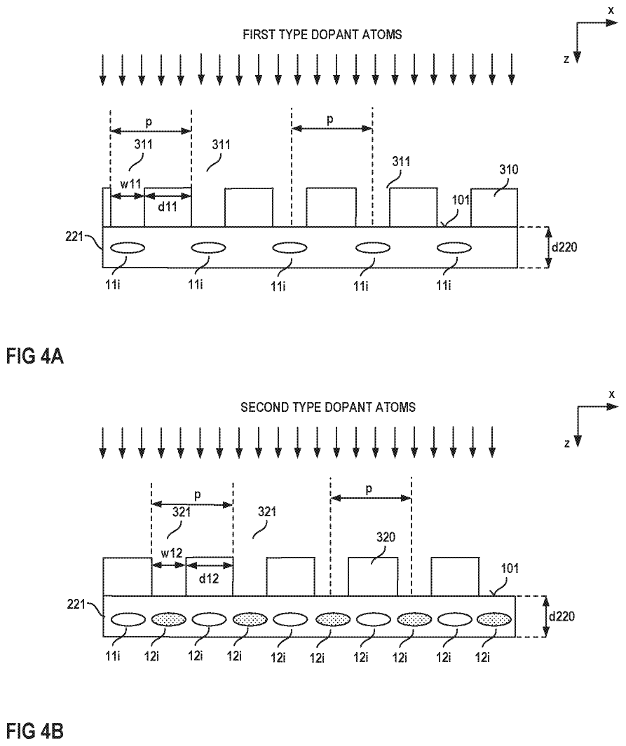

Referring to the above, forming the superjunction region 1, 2 includes implanting first and second type dopant atoms into each of several semiconductor layers 221 formed one above the other. One example of a method for implanting first and second type dopant atoms into one of the semiconductor layers 221 is illustrated in FIGS. 4A-4B, each of which illustrates a vertical cross-sectional view of one semiconductor layer 221 during the implantation process.

FIG. 4A illustrates implanting first type dopant atoms into the semiconductor layer 221. This includes implanting the first type dopant atoms through openings of a first implantation mask 310 provided above a surface of the semiconductor layer 211 into the semiconductor layer 221. The openings 311 in the first implantation mask 310 are spaced apart from each other in the first lateral direction x. The first type dopant atoms are implanted through the openings 311 into the semiconductor layer 221, so that the openings 311 define the position and size of the first implanted regions 11i in the semiconductor layer 221.

Referring to the above, the first regions 11 may be elongated in the second lateral direction y. In this example, the openings 311 in the first implantation mask 310 are elongated in the second lateral direction y.

The amount of dopant atoms included in each of the first regions 11i is essential to the functionality of the superjunction transistor device. At a given implantation dose, the amount of dopant atoms included in each of the first implanted regions 11i can be adjusted by suitably selecting a width w11 of the openings 311. The width w11 is the dimension of the openings 311 in the first lateral direction x. Adjacent openings 311 are spaced apart from each other by a distance d11 in the first lateral direction x.

According to one example, the openings 311 in the first implantation mask 310 have substantially the same width w11, so that each of the first implanted regions 11i in the semiconductor layer 221 substantially includes the same amount of dopant atoms.

In the following, Dz₁ denotes the implantation dose in the implantation process illustrated in FIG. 4A. This implantation dose is referred to as first implantation dose Dz₁ in the following. The first implantation dose Dz1 denotes the amount of first type dopant atoms directed towards the first surface 101 of the semiconductor body 100 in the vertical direction z.

The first implantation dose Dz₁ denotes the overall implantation dose in the implantation process. If, for example, the implantation process includes two or more implantation steps using different implantation energies (as explained herein further below) the implantation dose Dz₁ denotes the overall implantation dose in the individual implantation steps.

In the implantation process, the size of the openings 311 defines how much of the first type dopant atoms reach the first surface 101 and are introduced into the semiconductor body 100. In the following, the implanted dose A₁₁ᵢ denotes the amount of dopant atoms included in a first implanted region 11i after the process illustrated in FIG. 4A. The implanted dose A₁₁ᵢ is given by the first implantation dose Dz₁ multiplied with the width w11 of the openings 311 in the first implantation mask 310,

A₁₁ᵢ=DZ₁·w11 (1a).

The dimension of the first implantation dose Dz₁ is dopant atoms per square centimeter (cm⁻²), for example, so that the dimension of the implanted dose A₁₁ᵢ is dopant atoms per centimeter (cm⁻¹). Thus, the implanted dose A₁₁ᵢ denotes the amount of dopant atoms in each first region 11i per centimeter length in the second lateral direction y.

FIG. 4B illustrates implanting second type dopant atoms into the semiconductor layer 221. This includes forming a second implantation mask 320 on top of a surface of the semiconductor layer 221. The second implantation mask 320 includes openings 321 which are spaced apart from each other in the first lateral direction x. The first type dopant atoms are implanted through the openings 321 into the semiconductor layer 221, so that the openings 321 define the position and size of the second implanted regions 12i in the semiconductor layer 221.

Referring to the above, the first regions 11 may be elongated in the second lateral direction y. In this example, the openings 321 in the second implantation mask 320 are elongated in the second lateral direction y.

At a given implantation dose, the amount of dopant atoms included in each of the second implanted regions 12i can be adjusted by suitably selecting a width w12 of the openings 321. The width w12 is the dimension of the openings 321 in the first lateral direction x. Adjacent openings 321 are spaced apart from each other by a distance d12 in the first lateral direction x.

According to one example, the openings 321 in the second implantation mask 321 have substantially the same width w12, so that each of the second implanted regions 12i in the semiconductor layer 221 substantially includes the same amount of dopant atoms.

In the following, Dz2 denotes the implantation dose in the implantation process illustrated in FIG. 4B. This implantation dose is referred to as second implantation dose Dz₂ in the following. The second implantation dose Dz₂ denotes the amount of second type dopant atoms directed towards the first surface 101 of the semiconductor body 100 in the vertical direction z.

Similarly to the first implantation dose, Dz₁, the second implantation dose Dz₂ denotes the overall implantation dose in the implantation process.

In the implantation process, the size of the openings 321 defines how much of the second type dopant atoms reach the first surface 101 and are introduced into the semiconductor body 100. In the following, the implanted dose A12i denotes the amount of dopant atoms included in a second implanted region 12i after the process illustrated in FIG. 4B. The implanted dose A12i is given by the second implantation dose Dz₁ multiplied with the width w12 of the openings 321 in the second implantation mask 320,

$${A}_{12 i} = {Dz}_{2} \cdot w 12. \qquad ( 1 b )$$

Similarly to the first implantation dose, the dimension of the second implantation dose Dz₂ is dopant atoms per square centimeter (cm⁻²), for example, so that the dimension of the implanted dose A₁₂ᵢ is dopant atoms per centimeter (cm⁻¹).

According to one example, the implantation doses Dz1, Dz2 in the first and second implantation process are selected from between 2E12 cm⁻² and 2E13 cm⁻². The widths w11, w12 of the openings 311, 312 the implantation masks are selected from between 0.5 micrometers (μm) and 2 micrometers, for example. In these examples, the implanted doses A11i, A12i are in a range of between 1E8 cm⁻¹ and 1E9 cm⁻¹.

According to one example, the openings 311 in the first implantation mask 310 and the openings 312 in the second implantation mask 320 have substantially the same width, so that w11~w12, and the first implantation dose Dz₁ substantially equals the second implantation dose Dz₂, so that Dz₁~Dz₂. In this example, the first and second implanted regions 11i, 12i in the semiconductor layer 221 substantially include the same amount of dopant atoms, that is, the same implanted dose, A₁₁ᵢ~A₁₂ᵢ.

According to one example, lateral positions of the openings 311 in the first implantation mask 310 and lateral positions of the openings 321 in the second implantation mask 320 are adjusted such that, after the first and second implantation processes, each first implanted region 11i is arranged substantially in the middle between two adjacent second implanted regions 12i in the first lateral direction x and each second implanted regions 12i is arranged substantially in the middle between two adjacent first implanted regions 11i.

In the example illustrated in FIGS. 4A-4B, the first type dopant atoms are implanted in the semiconductor layer 221 before the second type dopant atoms are implanted. This, however, is only an example. The order in which the first and second type dopant atoms are implanted is arbitrary.

In FIGS. 4A-4B, sidewalls of the first and second openings 311, 312 in the first and second implantation masks 310, 320 are drawn to be vertical. This, however, is only an example and only for illustration purposes. The sidewalls of the openings 311. 312 may be beveled with either a positive or a negative bevel, so that the widths w11, w12 and mutual distances d11, d12 may vary over the depths of the openings 311, 321. Thus, as used herein, “width w11 of a first opening 311” denotes the average width of the respective first opening 311; “width w12 of a second opening 312” denotes the average width of the respective second opening 312; “distance d11 between two first openings 311” denotes the average distance between the respective first openings 311, and “distance d12 between two second openings 321” denotes the average distance between the respective second openings 312.

Referring to FIG. 1, the superjunction region 1 has a pitch p, which is the dimension of a pair including a first region 11 and a second region 12 in the first lateral direction x. The pitch p is also given by a center-to-center distance between two neighboring first regions 11, or a center-to-center distance between two neighboring second regions 12.

Referring to FIGS. 4A-4B, the pitch p of the superjunction region 1 is defined by the first and second implantation masks 310, 320 which have the same pitch p. More specifically, the pitch p is defined by a center-to-center distance between adjacent openings 311 in the first implantation mask 310 and a center-to center-distance between adjacent openings 312 in the second implantation mask 320.

According to one example, a width w11, w12 of the openings 311, 321 in the first and second implantation mask 310 is selected from between 20% and 40%, in particular between 30% and 45% of the pitch, so that adjacent first and second implanted regions 11i, 12i are spaced apart from each other in the lateral direction x.

Referring to FIG. 5, forming the transistor device further includes forming a further semiconductor layer 230 on top of the layer stack 220 and forming transistor cells 4 in the third semiconductor layer 230. The transistor cells 4 are only schematically illustrated in FIG. 5. Detailed examples of the transistor cells are explained herein further below. The first semiconductor layer 230 formed on top of the layer stack 220, that is, on top of the uppermost layer 220_{N} of the layer stack 220, forms the first surface 101 of the semiconductor body 100 and may be referred to as top layer.

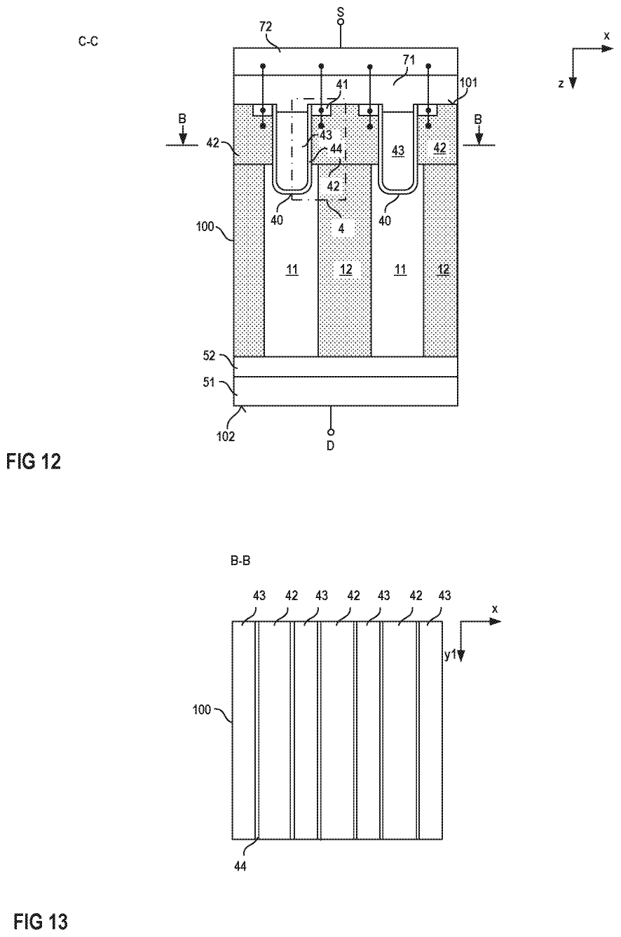

Forming the transistor cells 4 may include implantation processes and one or more annealing processes. In particular, forming body regions of the transistor cells (see 42 in FIG. 12) may include a relatively long annealing process. The same annealing process(es) may be used to form the superjunction regions 1 based on the first and second implanted regions 11i, 12i and the transistor cells 4 based on dopant atoms implanted into the further semiconductor layer 230.

Referring to the above, applying a voltage between the drain node D and the source node S in the off-state of the transistor device has the effect that space charge region (depletion regions) expand in the first and second regions 11, 12 beginning at PN junctions formed between adjacent first and second regions 11, 12. In the transistor device according to FIGS. 1 and 2, PN junctions between adjacent first and second regions 11, 12 extend in the vertical direction z and the second lateral direction y. The depletion regions substantially expand in directions perpendicular to the PN junctions, so that in the transistor device according to FIGS. 1 and 2, the depletion region expand in the first lateral direction x.

It should be noted that “PN junction” as used herein denotes any kind of junction (border) between adjacent first and second regions 11, 12. In particular, the PN junction is at a position between adjacent first and second regions at which an effective doping concentration is substantially zero. The presence of the PN junction not necessarily requires that adjacent first and second regions 11, 12 adjoin one another. It is also possible that adjacent first and second regions are spaced apart from each other, with a region having the basic doping of the semiconductor layer 221 arranged therebetween.

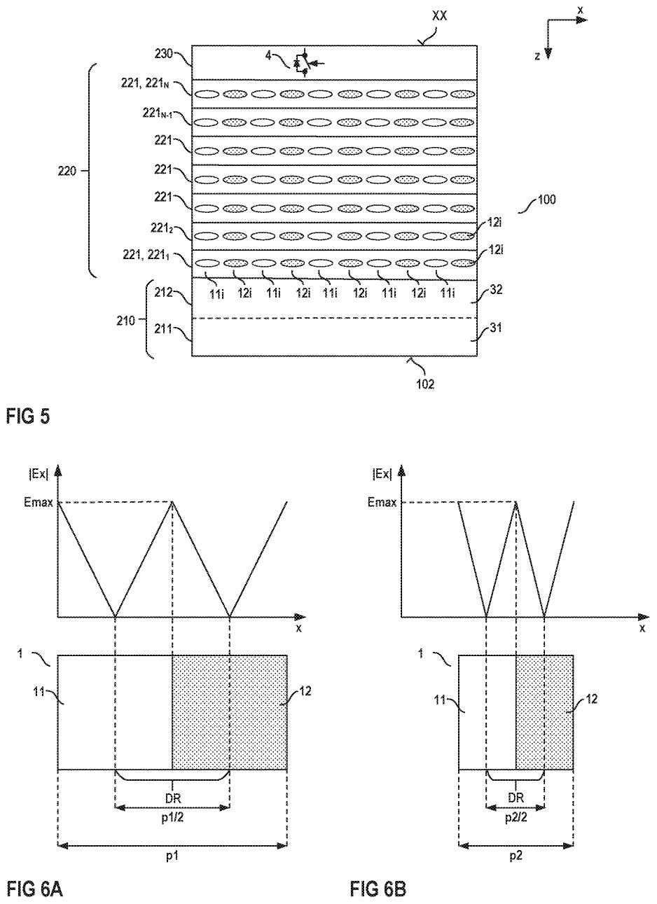

The expansion of the depletion regions in the first and second regions 11, 12 is associated with an electric field, which is referred to as lateral electric field in the following. The expansion of the depletion region and the associated lateral electric field is explained with reference to FIGS. 6A-6B in the following.

Each of FIGS. 6A-6B illustrates parts of two neighboring first and second regions of a superjunction region 1, wherein the superjunction region 1 illustrated in FIG. 6A has a first pitch p1 and the superjunction region illustrated in FIG. 6B has a second pitch p2 smaller than the first pitch p1. The semiconductor body 100 may have an inner region, which is a region in which the transistor cells are arranged, and an edge region surrounding the inner region and including an edge termination structure, for example. This is basically known, so that no further explanation is required in this regard.

In the inner region each first region 11 is arranged between two second regions 12 and each second region 12 is arranged between two first regions 11. In this case, a pair of neighboring first and second regions 11, 12 is entirely depleted when the depletion region in the first lateral direction x has reached the middle of each of the first and second regions 11, 12. This is schematically illustrated in FIGS. 6A and 6B in which DR denotes the depletion region.

In addition to the first and second regions 11, 12, FIGS. 6A-6B illustrate the lateral electric field Ex. More specifically, FIGS. 6A-6B illustrate the magnitude (field strength) of the lateral electric field Ex. FIGS. 6A-6B illustrate the scenario in which the first and second regions 11, 12 are entirely depleted, so that the magnitude of the lateral electric field reaches its maximum Emax. The value of this maximum at a certain vertical position z in the superjunction region 1 is dependent on a lateral dopant dose of the first and second regions 11, 12 at this vertical position. The lateral dopant dose of the first region 11 is the integral of the doping concentration of the first region 11 in the first lateral direction x, and the lateral dopant dose of the second region 12 is the integral of the doping concentration of the second region 12 in the first lateral direction x. Basically, the higher the lateral dopant dose at a respective vertical position z the higher the maximum Emax of the electric field.

According to one example, the lateral dopant doses of the first and second regions 11, 12 are selected such that the maximum of the field strength of the electric field is below a critical value. When the field strength would reach the critical value an Avalanche breakdown may occur, which is undesirable. The critical value of the electric field and the dopant dose that may result in the electric field reaching the critical value is dependent on the type of semiconductor material of the semiconductor body 100. This is common knowledge in the field of superjunction devices, so that no further explanation is required in this regard.

In the following, Dx₁₁ denotes the lateral dopant dose of a first region 11 at a certain vertical position z. This lateral dopant dose Dx₁₁ is referred to as first lateral dopant dose in the following. The first lateral dopant dose Dx₁₁ is given by the integral of the doping concentration of the first region 11 in the first lateral direction x, that is, the direction substantially perpendicular to the PN junctions between adjacent first and second regions 11, 12. Equivalently, Dx12 denotes the lateral dopant dose of a second region 12 at a certain vertical position z. This lateral dopant dose is referred to as second lateral dopant dose in the following. The second lateral dopant dose Dx₁₂ is given by the integral of the doping concentration of the second region 12 in the first lateral direction x, that is, the direction substantially perpendicular to the PN junctions.

The first and second lateral dopant doses Dx₁₁, DX₁₂ can be adjusted by suitably selecting the amount of dopant atoms (the implanted doses A₁₁ᵢ, A₁₂ᵢ) in the first and second implanted regions 11i, 12i. As explained above, in the annealing process first type dopant atoms in the first implanted regions 11i and second type dopant atoms in the second implanted regions 12i diffuse in the vertical direction z (and the lateral directions), so that the dopant atoms disperse in the vertical direction z and each of the first implanted regions 11i forms a portion of a respective first region 11 and each of the second implanted regions 12i forms a portion of a respective second region 12. The amount of first type dopant atoms included in a portion of a first region 11 formed by a respective first implanted region 11i substantially equals the amount of first type dopant atoms (the implanted dose A₁₁ᵢ) in the first implanted region 11i, and the amount of second type dopant atoms included in a portion of a second region 12 formed by a respective second implanted region 12i substantially equals the amount of second type dopant atoms (the implanted those A₁₂ᵢ) in the second implanted region 12i.

After the annealing process, the first and second type dopant atoms are not homogeneously distributed in the first and second regions 11, 12 in the vertical direction z, so that the lateral dopant doses Dx₁₁, Dx₁₂ may vary in the vertical direction. Nevertheless, an approximation of the lateral dopant dose in a section of a first region 11 resulting from a first implanted region 11i is given by an average <Dx₁₁> of the first lateral dopant dose Dx₁₁, and an approximation of the lateral dopant dose in a section of a second region 12 resulting from a second implanted region 12i is given by an average <DX₁₂> of the second lateral dopant dose Dx₁₂.

The average <Dx₁₁> of the first lateral dopant dose Dx₁₁ in a section of a first region 11 resulting from a first implanted region 11i with an implanted dose A₁₁ᵢ is given by

$$< {Dx}_{11} > = {A}_{11 i} \cdot d 221 , \qquad ( 2 a )$$

where d221 denotes a thickness of the semiconductor layer 221 in which the first implanted region 11i has been formed. Equivalently, an average <Dx₁₂> of the second lateral dopant dose Dx₁₂ in a section of a first region 11 resulting from a first implanted region 11i with an implanted dose A₁₁ᵢ is given by

$$< {Dx}_{12} > = {A}_{12 i} \cdot d 221 , \qquad ( 2 b )$$

where d221 denotes a thickness of the semiconductor layer 221 in which the second implanted region 12i has been formed.

As can be seen from equations (2a) and (2b) a variation of the lateral dopant doses in the vertical direction can be achieved by varying the implanted doses introduced into the individual semiconductor layer 221.

Referring to the above, the first and second type dopant atoms are not homogeneously distributed in the vertical direction z after the annealing process. Thus, even if each of the first implanted regions 11i regions had the same amount A₁₁ᵢ of first type dopant atoms, the profile of the first lateral dopant dose Dx₁₁ in the vertical direction would not be constant. Equivalently, even if each of the second implanted regions 12i regions had the same amount A₁₂ᵢ of second type dopant atoms, the profile of the second lateral dopant dose Dx₁₂ in the vertical direction would not be constant. This variation of the lateral dopant dose is illustrated in FIG. 8.

FIG. 8 illustrates the lateral dopant dose Dx₁₁ in one first region 11 or the lateral dopant dose Dx₁₂ in one second region 12 in the vertical direction z between an upper end and a lower end of the superjunction region 1. The upper end of the superjunction region 1 is at a vertical position z0, and the lower end of the superjunction region 1 is at a vertical position z1 illustrated in FIG. 1. The upper end faces the first surface 101 and is at a junction between the superjunction region 1 and the transistor cells 4. The lower end faces the second surface 102 and is at a junction between the superjunction region 1 and the buffer region 52 or the drain region 51.

As can be seen from FIG. 8, the lateral dopant doses Dx₁₁, Dx₁₂ vary and include several maxima and minima. The maxima are essentially at vertical positions of the implanted regions 11i, such as in the middle of the semiconductor layers 221, and the minima are essentially at vertical positions between two adjacent semiconductor layers 221 in the layer stack 220 explained before.

The maximum Emax of the electric field is mainly dependent on the lateral dopant doses and substantially not dependent on how the dopant atoms are distributed over the first and second regions 11, 12 in the first lateral direction x. This is illustrated in FIGS. 6A-6B. In the example illustrated in FIG. 6B the first and second regions 11, 12 have the same lateral dopant dose as the first and second regions 11, 12 in the example illustrated in FIG. 6A. Thus, in both examples the electric field reaches the same maximum Emax although the superjunction regions have different pitches p1, p2.

Referring to the above, in the on-state of the transistor device, each of the first regions 11 provides a conducting channel in the superjunction region 1 between the transistor cells 1 and the drain and buffer regions 51, 52. The electrical resistance of one first region 11 is substantially defined by the effective amount of first type dopant atoms included in the first region 11 and not by how the dopant atoms are distributed in the first lateral direction x. Thus, the first region 11 in the superjunction region 1 with the smaller pitch p2 according to FIG. 6B may substantially have the same resistance as the first region 11 in the superjunction region 1 with the greater pitch p1. The first region 11 has an effective doping concentration of the first doping type. That is, an overall number of first type dopant atoms in the first region 11 prevails and overall number of second type dopant atoms that may also be included in the first region 11. The effective amount of first type dopant atoms is the excess of first type dopant atoms over the second type dopant atoms in the first region 11.

The on-resistance Ron of a transistor device of the type illustrated in FIG. 1 is the electrical resistance of the transistor device between the drain node D and the source node S in the on-state. The on-resistance is substantially defined by the overall electrical resistance of the first regions 11 in the superjunction region 1. The (area) specific on-resistance Ron A is the on-resistance Ron multiplied with the area A of the transistor device. The area A of the transistor device is substantially given by an area of the semiconductor body 100 in a horizontal plane defined by the first and second lateral directions x, y.

As explained with reference to FIGS. 6A-6B, the pitch of the superjunction region 1 can be reduced without causing an increase of the maximum of the electric field and without increasing the electrical resistance of the individual first regions 11. Reducing the pitch p, however, increases the number of first regions 11 that can be implemented in the transistor device having a given area, so that reducing the pitch p may help to decrease the specific on-resistance. This is schematically illustrated in FIG. 8.

FIG. 8 shows a curve that illustrates the dependency of the specific on-resistance Ron·A on the pitch p. FIG. 8 is based on simulations of transistor devices of the type illustrated in FIG. 1, wherein the simulated transistor devices have the same voltage blocking capability and wherein the maximum of the lateral electric field in the superjunction region 1 is substantially the same in each of the transistor devices.

As can be seen from FIG. 8, reducing the pitch within a certain range results in a decrease of the specific resistance Ron·A. However, as can be seen from FIG. 8, the specific on-resistance reaches a minimum at a certain pitch, which is referred to as optimum pitch p_opt in the following, and increases as the pitch is reduced to below the optimum pitch p_opt. Such increase of the specific resistance may result from an increased impact of a lateral diffusion of second type dopant atoms from the second regions 12 into the first regions 11, thereby reducing the effective amount of first type dopant atoms in the first regions 11.

Ideally, the first and second regions 11, 12 in the transistor device are either directly adjacent to each other or are spaced apart from each other in the first lateral direction x and there is no lateral diffusion of first type dopant atoms from a first region 11 into an adjacent second region 12 and from a second region 12 into an adjacent first region 11. That is, in the annealing process for forming the first and second regions 11, 12 based on the first and second implanted regions 11i, 12i it is undesirable for the first type dopant atoms to diffuse into the second regions 12 and for the second type dopant atoms to diffuse into the first regions 11. A diffusion of first type dopant atoms into the second region 12 reduces the amount of first type dopant atoms available in the first regions 11 to conduct the current flow and thus increases the on-resistance.

The first and second lateral dopant doses Dx₁₁, Dₓ₁₂ explained above are the overall (absolute) first and second lateral dopant doses resulting from the respective implantation process. The effective first lateral dopant dose Deffₓ₁₁ is the integral in the first lateral direction x of the effective doping concentration of the first doping type in a first region 11 at a respective vertical position, and the effective second lateral dopant dose Deffₓ₁₂ is the integral in the first lateral direction x of the effective doping concentration of the second doping type in a second region 12 at a respective vertical position. Due to an (almost inevitable) diffusion of first type dopant atoms from a first region 11 into an adjacent second region 12 and from a second region 12 into an adjacent first region 12 the effective first lateral dopant dose Deffₓ₁₁ is lower than the absolute first lateral dopant dose Dx₁₁ and the second lateral dopant dose Deffₓ₁₂ is lower than the absolute second lateral dopant dose Dx₁₂.

An ineffective first lateral dopant dose Dinx11 is the integral in the first lateral direction x of the doping concentration of the first doping type in a second region 12 (of the second doping type) at a respective vertical position, and an ineffective second lateral dopant dose Dinx12 is the integral in the first lateral direction x of the doping concentration of the second doping type in a first region 11 (of the first doping type) at a respective vertical position. Basically, the stronger the lateral diffusion the higher the ineffective first or second lateral dopant Dinₓ₁₁, Dinₓ₁₂ relative to the respective absolute first or second lateral dopant Dx₁₁, Dx₁₂ and the lower the effective first or second lateral dopant Deffₓ₁₁, Deffₓ₁₂ relative to the respective absolute first or second lateral dopant doses Dx₁₁, Dx₁₂.

The effective first lateral dopant dose Deffₓ₁₁ (in the first regions 11) substantially defines the on-resistance. An average of the effective first lateral dopant dose Deffₓ₁₁ of a first region 11 is the average of the effective first lateral dopant dose Deffₓ₁₁ over the length of the respective first region 11 in the vertical direction z. Referring to the above, the first regions 11 are formed by the same processes, so that each of the first regions 11 has substantially the same profile of the absolute lateral dopant dose Dx₁₁ (and the effective first lateral dopant Deffₓ₁₁) and substantially the same average of the absolute first lateral dopant dose Deffₓ₁₁ (and the absolute first lateral dopant Dx₁₁). Basically, the higher the average of the effective first lateral dopant dose Deffₓ₁₁ at a given number and size of the first regions 11, the lower the on-resistance of the transistor device.

A reduction of the pitch may require a reduction of the diffusion in the lateral directions in order to avoid a decreasing effective first lateral dopant dose Deffₓ₁₁ and an increasing ineffective first lateral dopant dose Deffₓ₁₁ at a given absolute first lateral dopant dose Dx₁₁.

In the annealing process, the first and second type dopant atoms diffuse in the first lateral direction x substantially to the same extent as in the vertical direction z, so that the diffusion in the lateral directions can only be reduced by reducing, at the same time, the required diffusion in the vertical direction z. As explained above, the diffusion in the vertical direction z, however, is desired in order to be able to produce the first and second regions 11, 12 based on the first and second implanted regions 11i, 12i.

By reducing the thickness d221 of the second semiconductor layers 221 the required vertical diffusion and, at the same time, the (inevitable) lateral diffusion of the dopant atoms can be reduced. Thus, a reduction of the pitch p in order to decreases the specific on-resistance may be associated with a reduction of the thickness d221 of the semiconductor layers 221 in the layer stack 220.

The voltage blocking capability, which is the maximum voltage that the transistor device can withstand in the off-state, is substantially dependent on the dimension of the superjunction region 1 in the vertical direction z. Thus, reducing the thickness d221 of the individual semiconductor layers 221 may make it necessary to increase the overall number of semiconductor layers 221 in order to maintain a certain voltage capability.

According to one example, the transistor device is implemented to have a voltage blocking capability selected from between 600V and 800V in particular between 600V and 700V.

Considering FIG. 8 and considering the lateral diffusion issue explained hereinabove, it has been found that in a superjunction transistor device based on a semiconductor body 100 including monocrystalline silicon a pitch p selected from between 3 micrometers and 5 micrometers, in particular between 3 micrometers and 4.5 micrometers in combination with a layer thickness d221 selected from between 1.9 micrometers and 2.5 micrometers, in particular between 1.9 micrometers and 2.1 micrometers results in favorable specific on-resistance Ron. A.

Referring to the above, the overall number of the first semiconductor layers 221 in the layer stack 220 affects the voltage blocking capability. According to one example, in order to achieve a voltage blocking capability of between 600V and 800V the overall number of semiconductor layers is selected from between 17 and 21.

At a given number of semiconductor layers 221, the voltage blocking capability can be increased by increasing the thickness d221 of the semiconductor layers 221. At a given thickness of the semiconductor layers 221, the voltage blocking capability can be increased by increasing the overall number of semiconductor layers. Just for explanation purposes, the parameters of three different examples of transistor devices are summarized in the following. The parameters in these examples include the voltage blocking capability Vbr, the pitch p, the number N221 of semiconductor layers 221 and the thickness d221 of the individual semiconductor layers 221. The temperature of the annealing process is selected from between 950° C. and 1150° C., and the duration is selected from between 20 minutes and 400 minutes, for example. Basically, the higher the temperature, the shorter the duration. Furthermore, The smaller the pitch, the shorter the duration of the annealing process at a given temperature.

### EXAMPLE 1

Voltage blocking capability (Vbr): 600V
Pitch (p): 4.4 micrometers
Number of layers (N221): 19

Layer thickness (d221) 2.1 micrometers

### EXAMPLE 2

Voltage blocking capability (Vbr): 650V
Pitch (p): 4.4 micrometers
Number of layers (N221): 19
Layer thickness (d221) 2.15 micrometers

### EXAMPLE 3

Voltage blocking capability (Vbr): 600V
Pitch (p): 3 micrometers
Number of layers (N221): 19
Layer thickness (d221) 2.1 micrometers

As can be seen from examples 1 and 2, slightly increasing the layer thickness d221 may result in an increased voltage blocking capability (at the cost of a slightly increased on-resistance).

The reduction of the pitch may be supported by additional measures in the manufacturing process that take into account the inevitable lateral diffusion in the annealing process.

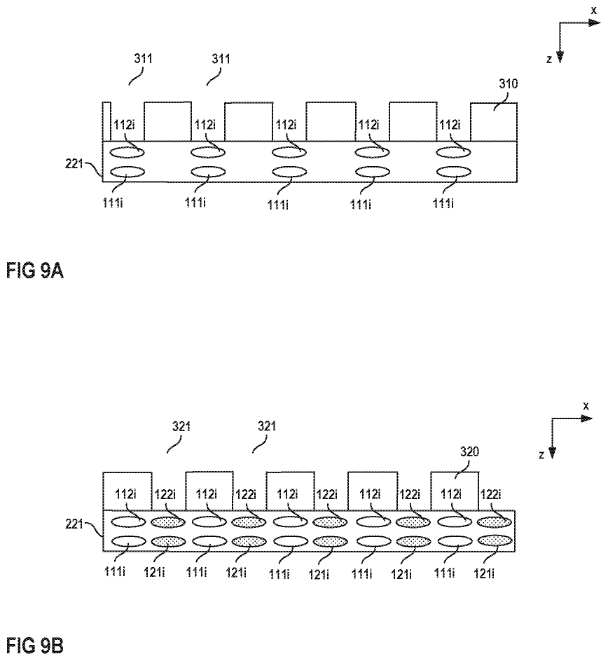

According to one example, each of the first implantation process and the second implantation process includes two or more implantation steps. One example of a method in which each of the first and second implantation processes includes two implantation steps is illustrated in FIGS. 9A-9B.

FIG. 9A shows a vertical cross-sectional view of one semiconductor layer 221 after the first implantation process. In this implantation process first type dopant atoms are implanted in the semiconductor layer 221 via the openings 311 in the first implantation mask 310 in two implantation steps, a first implantation step forming implanted regions 111i at a first vertical position of the semiconductor layer 221 and a second implantation step forming implanted regions 112i at a second vertical position different from the first vertical position. The implantation dose in the first and second implantation steps can be substantially equal or can be different.

FIG. 9B shows a vertical cross-sectional view of one semiconductor layer 221 after the second implantation process. In this implantation process second type dopant atoms are implanted in the semiconductor layer 221 via the openings 312 in the second implantation mask 320 in two implantation steps, a first implantation step forming implanted regions 121i at a first vertical position of the semiconductor layer 221 and a second implantation step forming implanted regions 122i at a second vertical position different from the first vertical position. The implantation dose in the first and second implantation steps can be substantially equal or can be different.

According to one example, vertical positions of the implanted regions 111i, 112i in the first implantation process illustrated in FIG. 9A and the implanted regions 121i, 122i in the second implantation process illustrated in FIG. 9B are selected such that in a layer stack including a plurality of semiconductor layers of the type illustrated in FIG. 9B implanted regions 111i, 112i resulting from the first implantation process are substantially evenly spaced in the vertical direction z and implanted regions 121i, 122i resulting from the second implantation process are evenly space in the vertical direction z.

Referring to FIGS. 9A-9B in both the first implantation process and the second implantation process two implanted regions are formed spaced apart from each other in the vertical direction z in the semiconductor layer 221 below the opening 311, 321 of the respective implantation mask. The presence of two implanted regions 111i. 112i and 121i, 122i which are vertically spaced apart from each other makes it possible to either reduce the diffusion of the implanted dopant atoms in the annealing process or to increase the thickness d221 of the semiconductor layer 221 in order to reduce the overall number of semiconductor layers 221.

That is, at a given layer thickness d221 the duration of the annealing process can be reduced, thereby reducing the lateral diffusion and enabling a reduction of the pitch p. Alternatively, at a given annealing process, the presence of forming two implanted regions in each implantation process makes it possible to increase the layer thickness, which helps reduce the number of semiconductor layers 221 which are to be produced and thus the costs associated with the manufacturing process.

In the manufacturing process of the superjunction region 1 there are two possible effects that may cause a stronger diffusion of dopant atoms in semiconductor layers 221 arranged closer to the drain and a buffer regions 51, 52 than in semiconductor layers 221 arranged closer to the transistor cells 4.

As explained above, the layer stack 220 with the semiconductor layers 221 may be formed on top of a substrate 211. The substrate 211 may include oxygen and voids, in particular, when the substrate 211 is based on a Czochralski (CZ) material. In the annealing process for forming the first and second regions 11, 12 the combination of oxygen and voids may cause interstitial to diffuse from the substrate 211 into the layer stack 220, with the interstitial concentration decreasing towards the first surface 101. The interstitials support the diffusion of first and second type dopant atoms included in the layer stack 220. As the interstitial concentration decreases towards the first surface 101, the diffusion of first and second type dopant atoms promoted by the interstitials is stronger in regions closer to the drain and the buffer regions 51, 52 than in regions closer to the first surface 101. This imbalance of the diffusion along the vertical direction z may result in a varying lateral dopant dose in the first and second regions 11, 12.

According to one example, in order to counteract such imbalance of the diffusion along the vertical direction z resulting from interstitials diffusing into the layer stack 220 from the substrate 211, the annealing process, at least partially, takes place in an oxidizing atmosphere. The temperature of the annealing process is selected from between 950° C. and 1150° C., and the duration is selected from between 20 minutes and 400 minutes, for example. Basically, the higher the temperature, the shorter the duration.

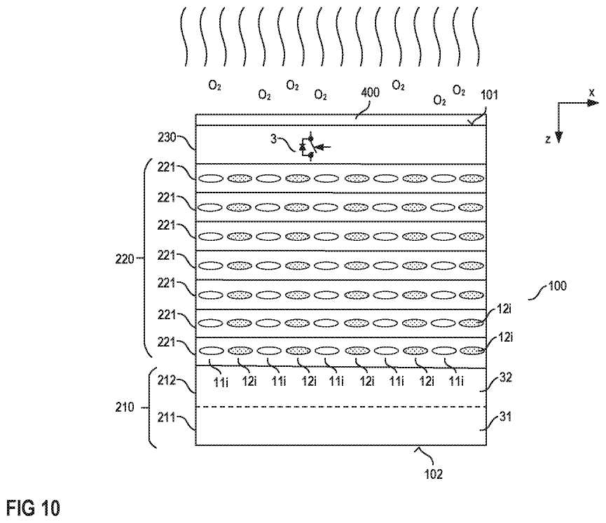

An annealing process in an oxidizing atmosphere is schematically illustrated in FIG. 10. In this annealing process an oxide layer 400 is formed on top of the first surface 101. This oxide layer 400 causes interstitials to diffuse via the first surface 101 into the semiconductor body 100, so that also in semiconductor layers 221 close to the first surface 101 there is a diffusion promoted by interstitials. This may help to at least partially counteract an imbalance of the lateral dopant doses resulting from interstitials diffusing into the layer stack 220 from the substrate 211.

Another reason that may cause a stronger diffusion of first and second type dopant atoms in semiconductor layers 221 closer to the drain and buffer regions 51, 52 is the temperature involved in the process of forming the semiconductor layers 221. Referring to the above, the semiconductor layers 221 are epitaxially grown layers, for example. The temperature during the epitaxial growth process may cause a diffusion of already implanted first and second type dopant atoms in semiconductor layers 221 formed before. In the layer stack 220, this has the effect that already before the annealing process for forming the first and second regions 11, 12 based on the first and second implanted regions 11i, 12i a diffusion of implanted dopant atoms may already have occurred to a certain extent in some of the semiconductor layers 221.

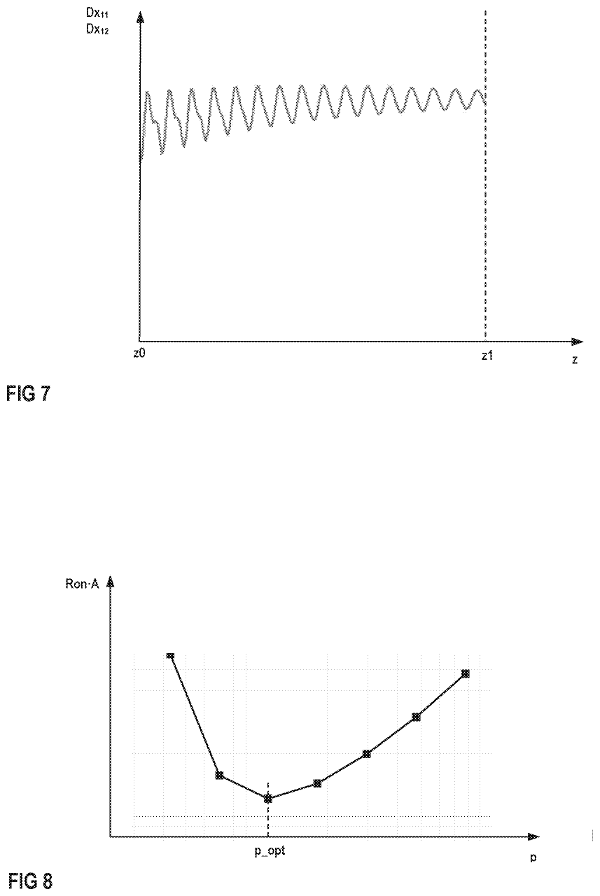

This effect can be seen from FIG. 7 which illustrates the lateral dopant doses in the first and second regions 11, 12. As can be seen from FIG. 7, ripples in the illustrated profile become lower towards the lower end z1 of the superjunction region 1. The semiconductor layer 2021 close to the lower end are produced first in the manufacturing process, so that there is a stronger diffusion in these semiconductor layers 221 in the overall manufacturing process.

The diffusion of first and second type dopant atoms in some of the semiconductor layers 221 already during the process of forming the individual semiconductor layers 221 not only reduces ripples in the lateral dopants doses but also may cause first and second type dopant atoms to diffuse in lateral directions more than desired. Thus, after the annealing process, first type dopant atoms in semiconductor layers to the drain and buffer regions 51, 52 may have diffused into second regions 12 and second type dopant atoms may have diffuse into first regions 11 more than desired. In other words, in the first and second regions 11, 12, the ineffective first lateral dopant dose Dinx11 and the ineffective second lateral dopant dose Dinx12 increases in the layer stack 220 towards the lowermost layer 221₁. This may locally increase the electrical resistance of the superjunction region 1.

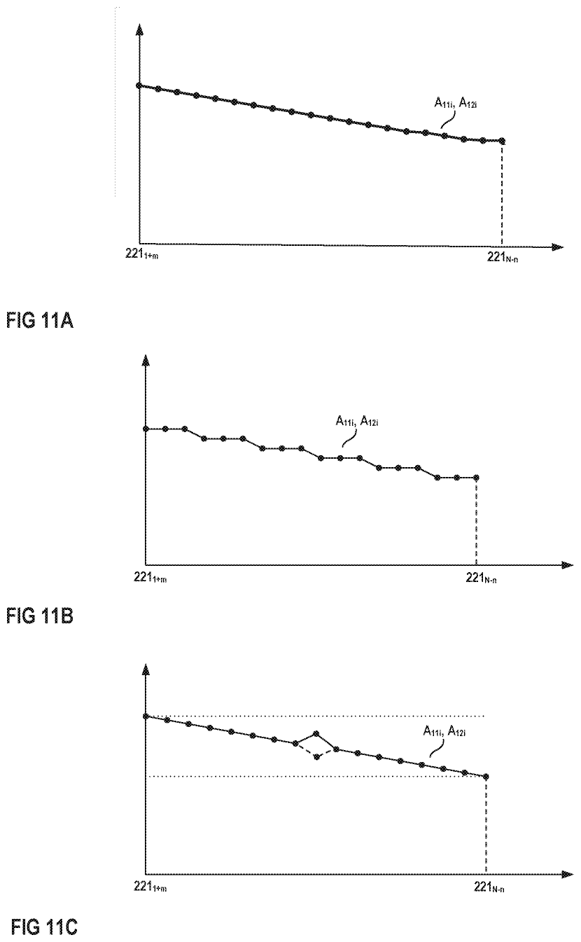

According to one example illustrated in FIG. 11A, in order to counteract the decreasing effective first lateral dopant dose Deffₓ₁₁ in the first regions 11 or the increasing ineffective first lateral dopant dose Dinₓ₁₁ in the second regions 12 towards the lowermost layer 221₁, at least one of the implanted doses A₁₁ᵢ, A₁₂ᵢ in at least a portion of the layer stack may be varied in the vertical direction z such that the implanted doses decrease towards the uppermost layer 221_{N} and increase towards the lowermost layer 221₁. According to one example, both of the implanted doses A₁₁ᵢ, A₁₂ᵢ decreases towards the uppermost layer 221₁. In this example, the variation of the doses in order to achieve the decrease towards can be the same or can be different.

FIG. 11A illustrates one example of the implanted doses in a portion of the layer stack 220 including the plurality of semiconductor layers 221 with the lowermost semiconductor layer 221₁ produced first and the uppermost semiconductor layer 221_{N} produced last in the layer stack 220. The portion of the layer stack illustrated in FIG. 11A includes an uppermost layer 221₁₊ₘ of the layer stack portion and a lowermost layer 221_{N-n} of the layer stack portion.

According to one example, the implanted doses A₁₁ᵢ, A₁₂ᵢ decrease towards the uppermost layer 221_{N} and increase towards the lowermost layer 221₁ over the entire layer stack 220. In this example, the uppermost layer 221_{N-n} of the layer stack portion equals the uppermost layer 221_{N} of the layer stack and the lowermost layer 221₁₊ₘ of the layer stack portion equals the lowermost layer of the layer stack 220.

According to another example, the doping situation in the lowermost semiconductor layer 221₁ and the uppermost semiconductor layer 221_{N} is slightly different from the doping situation in the other semiconductor layers of the layer stack, so that the layer stack portion (the doping situation of which is illustrated in FIG. 11A) may include the layer stack 220 except for the uppermost layer 221_{N} and the lowermost layer 221₁. That is, the layer stack portion may include the layer stack ranging from layer 221₂ to layer 221_{N-2} illustrated in FIG. 5

According to one example, the layer stack portion in which the implanted doses A₁₁ᵢ, A₁₂ᵢ decrease towards the first surface 101 and increase towards the second surface 102 includes at least 70%, 80%, or 90% of the layers 221 of the layer stack 220.

The implanted doses A₁₁ᵢ, A₁₂ᵢ may increase in the layer stack portion towards the second surface 102 (towards the lowermost layer 221₁ in the layer stack) in various ways.

According to one example illustrated in FIG. 11A, there is a steady increase of the implanted doses A₁₁ᵢ, A12i in the layer stack portion towards the lowermost layer 221₁₊ₘ such that the closer a respective layer to the lowermost layer 221₁₊ₘ in the layer stack portion, the higher the implanted dose. According to one example, the increase is substantially linear.

A steady increase, however, is only an example. It is also possible for the at least one implanted dose to increase in steps in such a way that two or more adjacent layers substantially have the same implanted dose A₁₁ᵢ, A12i and the doses increase towards the lowermost layer 221₁₊ₘ in the layer stack portion. This is illustrated in FIG. 11B.

According to another example illustrated in FIG. 11C, there is a local maximum or a local minimum (illustrated in dotted lines) of at least one of the dopant doses in the layer stack portion. The local maximum is lower than the absolute maximum of the at least one of the dopant doses at the lower end of the layer stack portion, or the local minimum is higher than the absolute minimum of the at least one of the dopant doses A₁₁ᵢ, A12i at the upper end of the layer stack portion.

According to one example, the implanted dose in the lowermost layer 220₁₊ₘ of the layer stack portion is more than 30% or more than 40% higher than in the uppermost layer 220_{N}, such as between 40% and 80%, in particular between 50% and 70%, higher.

According to one example, an increase of at least one of the dopant doses towards the lower end of the layer stack portion includes that overall implanted dose in the adjacent three lowermost layers of the layer stack portion is more than 30% or more than 40% higher than an overall implanted dose in the adjacent three uppermost layers of the layer stack portion. The adjacent three lowermost layers of the layer stack portion include the lowermost layer 221₁₊ₘ of the layer stack portion and the two adjacent layers. The adjacent three uppermost layers of the layer stack portion include the uppermost layer 221_{N-n} of the layer stack portion and the two adjacent layers.

According to one example, the layer stack portion in which the overall implanted dose in the three lowermost layers is more than 30% higher than the overall implanted dose in the three uppermost layers includes the entire layer stack 220 with the uppermost layer 221_{N} and the lowermost layer 221₁.

Each of FIGS. 11A-11C, represents one of the implanted doses A₁₁ᵢ, A₁₂ᵢ in each of the layers of the layer stack portion. According to one example, FIGS. 11A-11C represent both of the implanted doses A₁₁ᵢ, A12i. In this example, the implanted doses A₁₁ᵢ, A12i are substantially equal. Basically, it is also possible that the implanted doses A₁₁ᵢ, A12i in the same layer are different, for example, in order to counteract a basic doping of the semiconductor layer 221.

Referring to FIG. 12, each transistor cell 4 includes a source region 41 of the first doping type, a body region 42 of the second doping type (complementary to the first doping type), and a gate electrode 43. The gate electrode 43 is adjacent to the body region 42, is dielectrically insulated from the body region 42 by a gate dielectric 44 and is arranged in a gate trench 40 extending from the first surface 101 of the semiconductor body 100 into the semiconductor body 100.

Referring to FIG. 12, source and body regions 41, 42 of two neighboring transistor cells 4 may be arranged in a mesa region between neighboring gate trenches 40. In this example, the body regions 42 of the two neighboring transistor cells 4 may be formed by one contiguous doped region of the second doping type. Furthermore, two (other) neighboring transistor cells may share the gate electrode 43. That is, the gate electrodes 43 of two neighboring transistor cells may be formed by one contiguous electrode arranged in one gate trench 40.

The gate electrodes 43 include an electrically conductive material. Examples of the electrically conductive material include doped polysilicon, or a metal. The gate dielectric 44 includes an oxide, for example. According to one example, the oxide is silicon oxide (SiO₂).

Referring to the above, the source regions 41 of the transistor cells 4 are connected to the source node S of the transistor device. The transistor device may include a source electrode 72, which either forms the source node S or is connected to the source node S. The source electrode 72 includes an electrically conductive material such as, for example, aluminum (Al), copper (Cu), or an aluminum-copper alloy (AlCu).

The source electrode 72 is electrically connected to the source and body regions 41, 42 of the transistor cells 40. Connections between the source electrode 72 and the source and body regions 41, 42 are only schematically illustrated in FIG. 12. Such connections may be implemented using electrically conductive vias that extend from the source electrode 72 through an insulating layer 71 to the source and body regions 41, 42.

The gate electrodes 43 are connected to the gate node G. Connections between the gate electrodes 43 and the gate node G are not illustrated in FIG. 11. Examples of such connections are explained herein further below.

The insulating layer 71 is formed on top of the first surface 101 of the semiconductor body 100 and the gate electrodes 43 and separates the source electrode 72 from the semiconductor body 100 and the gate electrodes 43.

Referring to the above, the second regions 12 of the first superjunction region 1 are coupled to the source node S. In the example illustrated in FIG. 12, each of the second regions 12 adjoins the body region 42 of a respective transistor cell and is coupled to the source node S via the body region 42 of the transistor cell 4.

Forming the transistor cells 4 may include forming the gate electrodes 43 in the gate trenches 40, implanting first type dopant atoms to form the source regions 41, and implanting second type dopant atoms to form the body regions 42. The dopant atoms may be implanted before or after forming the gate electrodes 43. Forming the transistor cells 4 further includes an annealing process in which the implanted dopant atoms are activated. The annealing process can be the same annealing process used for activating the first and second superjunction regions 1, 2 and the first and second termination regions 31, 32.

Referring to the above, the transistor device can be operated in the on-state or the off-state. The transistor device is in the on-state when the gate-source voltage is such that a conducting channel is generated by the gate electrode 43 in the body region 42 along the gate dielectric. The transistor device is in the off-state when the conducting channel is interrupted. To enable a current flow from the source node S to the drain node D when the transistor device is in the on-state, that portion of the body region 42 in which the conducting channel is generated adjoins a respective first region 11. In this way, in the on-state, charge carriers can move from the source regions 41 along the conducting channels in the body regions 42, the first regions 11 of the first superjunction region 1 and the buffer region 52 to the drain region 51.

In the circuit symbols of the transistor cells 4 illustrated in FIG. 1, the electronic switch represents the conducting channel along the gate dielectric 44 in the body region 42. The diode in the circuit symbol represents a diode formed by a PN junction between the first region 11 (drift region) and the body region 42, which is usually referred to as body diode.

According to one example illustrated in FIG. 12, the gate trenches 40 with the gate electrodes are elongated. One example of elongated gate electrodes 43 is illustrated in FIG. 13.

FIG. 13 illustrates one portion of the semiconductor body 100 in a first horizontal section plane B-B shown in FIG. 11 that cuts through the gate trenches 40 with the gate electrodes 43 and the gate dielectrics 44. The horizontal sectional plane B-B is essentially parallel to the first and second surfaces 101, 102.

According to one example, as illustrated in FIGS. 12 and 13, the gate trenches 40 with the gate electrodes 43 are spaced apart from each other in the first lateral direction x and longitudinally extend in the second lateral direction y. In this example, the gate trenches 40 longitudinally extend in the same direction in which the first and second regions 11, 12 longitudinally extend. According to another example (not illustrated) longitudinal directions of the gate trenches 40 with the gate electrodes 43 are perpendicular to longitudinal directions of the first and second regions 11, 12.

According to one example, the transistor device is an N-type transistor device. In this example, the regions of the first doping type, such as the drain and buffer regions 51, 52, the first and third regions 11, 13, the first termination region 31 and the source regions 41 are N-type regions and the regions of the second doping type, such as the second and fourth regions 12, 22 and the second termination region 32 are P-type regions. An N-type transistor device is in the forward biased mode when a positive voltage is applied between the drain node D and the source node S. N-type dopant atoms for forming N-type regions are phosphorus (P) atoms, for example, and P-type dopant atoms for forming P-type regions are boron (B) atoms, for example.

According to another example, the transistor device is a P-type transistor device. In this example, the regions of the first doping type are P-type regions and the regions of the second doping type are N-type regions.

It should be noted that implementing the transistor cells 4 with gate electrodes 43 arranged in gate trenches 40, as illustrated in FIG. 12, is only an example. According to another example (not illustrated) the gate electrodes are a planar gate electrodes arranged above the first surface 101.

Referring to the above, the second termination region 32 is coupled to the source node S. One example of connecting the second termination region 32 to the source node S is illustrated in FIG. 13.

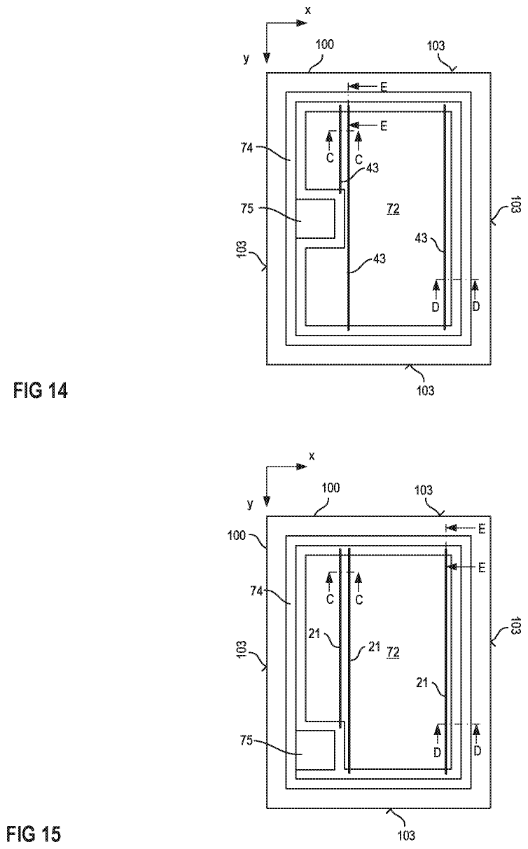

Each of FIGS. 14 and 15 illustrates a top view of a transistor device of the type explained herein before. More specifically, each of FIGS. 14 and 15 shows a top view of the semiconductor body 100 with the source electrode 72 and formed on top of the insulating layer 71.

The transistor device further includes a gate runner 74 and a gate pad 75 both formed on top of the insulating layer 71 and spaced apart from the source electrode 72. The gate runner 74 surrounds the source electrode 72 in lateral directions of the semiconductor body 100. The gate pad 75 forms the gate node G or is connected to the gate node G of the transistor device. The gate pad 75 may adjoin the gate runner 74, as illustrated in FIGS. 14 and 15. Alternatively, the gate pad 75 is spaced apart from the gate runner 74 and a resistor (gate resistor) is connected between the gate pad 75 and the gate runner 74.

In the example illustrated in FIG. 14, the gate pad 75 is arranged at a position that is essentially in the middle between two opposing sidewalls 103 of the semiconductor body 100. In the example according to FIG. 15, the gate pad 75 is arranged at a position that is close to a corner formed by two adjacent sidewalls 103 of the semiconductor body 100. The sidewalls 103 terminate the semiconductor body 100 in lateral directions.

The transistor cells are out of view in FIGS. 14 and 15. For the purpose of illustration, the position of three gate electrodes 43 relative to the source electrode 72 and the gate runner 74 are illustrated by bold lines in FIGS. 14 and 15. In the example illustrated in FIGS. 14 and 15, the gate electrodes 43 are elongated electrodes, wherein a longitudinal direction of the gate electrodes 43 corresponds to the second lateral direction y explained herein before. The vertical cross-sectional view of the transistor cells illustrated in FIG. 11 is a cross-sectional view in section planes C-C illustrated in FIGS. 14 and 15, for example.

In order to connect the gate electrodes 43 to the gate pad 75, regions of the gate electrodes 43 close to longitudinal ends of the gate electrodes 43 are connected to the gate runner 75. “Longitudinal ends” terminate the gate electrodes 43 in longitudinal directions, the longitudinal directions corresponding to the second lateral direction y in the examples illustrated in FIGS. 14 and 15. According to one example, the gate electrodes 43 are connected to the gate runner 74 by electrically conducting vias (not illustrated in the drawings) extending in the vertical direction through the insulating layer 71.

Some of the aspects explained above are summarized in the following with reference to numbered examples.

Example 1. A method for forming a superjunction device, the method including: forming a superjunction region, the superjunction region including a plurality of first regions of a first doping type and a plurality of second regions of a second doping type complementary to the first doping type, wherein forming the superjunction region includes: forming a plurality of semiconductor layers one above the other to form a layer stack; implanting first type dopant atoms through openings of a first implantation mask in each of the semiconductor layers to form first implanted regions; implanting second type dopant atoms through openings of a second implantation mask in each of the semiconductor layers to form second implanted regions; and an annealing process to diffuse and activate the implanted first type dopant atoms and second type dopant atoms, wherein each of the first implantation mask and the second implantation mask has a pitch selected from between 3 micrometers and 5 micrometers, and wherein each of the semiconductor layers has a thickness selected from between 1.9 micrometers and 3.5 micrometers.

Example 2. The method according to example 1, wherein the pitch is selected from between 3 micrometers and 4.5 micrometers.

Example 3. The method according to example 1 or 2, wherein the thickness is selected from between 1.9 micrometers and 2.5 micrometers.

Example 4. The method according to any one of examples 1 to 3, wherein a width of the openings in the first implantation mask and a width of the openings in the second implantation mask is selected from between 20% and 45% of the pitch.

Example 5. The method according to any one of examples 1 to 4, wherein the annealing process takes place in an oxidizing ambient.

Example 6. The method according to any one of examples 1 to 5, wherein the layer stack includes a lowermost semiconductor layer, wherein each of the first implanted regions has a first implanted dose and each of the second implanted regions has a second implanted dose, and wherein the first implanted regions and the second implanted regions are formed such that at least in a portion of the layer stack at least one of the first implanted dose and the second implanted dose increases towards the lowermost semiconductor layer over the portion of the layer stack.

Example 7. The method according to example 6, wherein the portion of the layer stack includes at least 70% of the layers of the layer stack.

Example 8. The method according to example 7, wherein a maximum of the at least one of the first implanted dose and the second implanted dose in the portion of the layer stack is at least 30% higher than a minimum of the first implanted dose in the portion of the layer stack.

Example 9. The method according to any one of examples 6 to 8, wherein the at least one of the first implanted dose and the second implanted dose steadily increases towards the lowermost semiconductor layer.

Example 10. The method according to any one of examples 6 to 8, wherein the at least one of the first implanted dose and the second implanted dose increases stepwise towards the lowermost semiconductor layer.

Example 11. The method according to any one of examples 6 to 8, wherein the at least one of the first implanted dose and the second implanted dose increases towards the lowermost semiconductor layer such that the at least one of the first implanted dose and the second implanted dose in a lowermost layer of the layer stack portion is more than 30% higher than the at least one of the first implanted dose and the second implanted dose in an uppermost lowermost layer of the layer stack portion.

Example 12. The method according to any one of examples 6 to 8, wherein the at least one of the first implanted dose and the second implanted dose increases towards the lowermost semiconductor layer such that an overall dose of the at least one of the first implanted dose and the second implanted dose in three adjacent lowermost layers of the layer stack portion is more than 30% higher than an overall dose of the at least one of the first implanted dose and the second implanted dose in three adjacent uppermost layers of the layer stack portion.

Example 13. The method according to example 12, wherein the layer stack portion includes the entire layer stack.

Example 14. The method according to any one of examples 6 to 13, wherein in each of the semiconductor layers of the portion of the layer stack the first implanted dose substantially equals the second implanted dose.

Example 15. The method according to any one of examples 1 to 14, wherein implanting the first type dopant atoms in each of the semiconductor layers includes at least two implantation steps at different implantation energies; and wherein implanting the second type dopant atoms in each of the semiconductor layers includes at least two implantation steps at different implantation energies.

Example 16. The method according to example 15, wherein the at least two implantation steps include exactly two implantation steps.

Example 17. The method according to any one of examples 1 to 16, wherein the number of semiconductor layers in the layer stack is selected from between 17 and 21.

Example 18. The method according to any one of examples 1 to 16, wherein forming the layer stack includes forming the layer stack on top of a carrier.

Example 19. The method according to example 18, wherein the carrier includes a semiconductor substrate and a semiconductor layer formed on the semiconductor substrate.

Example 20. The method according to any one of examples 1 to 19, further including: forming a further semiconductor layer on top of the layer stack; and forming transistor cells at least partially integrated in the further semiconductor layer.

Example 21. The method according to example 20, wherein forming the transistor cells includes an annealing process, and wherein the annealing process for forming the transistor cells and the annealing process for forming the superjunction region is the same annealing process.

Example 22. The method according to any one of examples 1 to 21, wherein the first implanted regions and the second implanted regions are formed to be spaced apart in a first lateral direction of the layer stack and to be elongated in a second lateral direction perpendicular to the first lateral direction.

Example 23. The method according to any one of examples 1 to 22, wherein the semiconductor layers include monocrystalline silicon.

Example 24. A superjunction device, including: a superjunction region including a plurality of first regions of a first doping type and a plurality of second regions of a second doping type complementary to the first doping type in a layer stack including a plurality of semiconductor layers formed one above the other to form a layer stack, wherein a pitch of the superjunction region is selected from between 3 micrometers and 5 micrometers, and wherein each of the semiconductor layers has a thickness selected from between 1.9 micrometers and 3.5 micrometers.

Example 25. The superjunction device according to example 24, wherein the layer stack includes a lowermost semiconductor layer, wherein each of the first regions has a first implanted dose and each of the second implanted regions has a second implanted dose in each of the layers of the layer stack, and wherein at least in a portion of the layer stack at least one of the first implanted dose and the second implanted dose increases towards the lowermost semiconductor layer over the portion of the layer stack.

Example 26. The superjunction device according to example 24 or 25, wherein the layer stack includes a lowermost semiconductor layer, and wherein in the second regions the ineffective lateral dopant dose of first type dopant atoms increases towards the lowermost semiconductor layer and in the first regions the ineffective lateral dopant dose of second type dopant atoms increases towards the lowermost semiconductor layer.

What is claimed is:

1. A method for forming a superjunction device, the method comprising:
forming a superjunction region, the superjunction region comprising a plurality of first regions of a first doping type and a plurality of second regions of a second doping type complementary to the first doping type,
wherein forming the superjunction region comprises:
forming a plurality of semiconductor layers one above the other to form a layer stack;
implanting first type dopant atoms through openings of a first implantation mask in each of the semiconductor layers to form first implanted regions;
implanting second type dopant atoms through openings of a second implantation mask in each of the semiconductor layers to form second implanted regions; and
an annealing process to diffuse and activate the implanted first type dopant atoms and second type dopant atoms to form the superjunction region,
wherein each of the first implantation mask and the second implantation mask has a pitch selected from between 3 micrometers and 5 micrometers, and
wherein each of the semiconductor layers has a thickness selected from between 1.9 micrometers and 3.5 micrometers.

2. The method of claim 1, wherein the pitch is selected from between 3 micrometers and 4.5 micrometers.

3. The method of claim 1, wherein the thickness is selected from between 1.9 micrometers and 2.5 micrometers.

4. The method of claim 1, wherein a width of the openings in the first implantation mask and a width of the openings in the second implantation mask are each selected from between 20% and 45% of the pitch.

5. The method of claim 1, wherein the annealing process takes place in an oxidizing ambient.

6. The method of claim 1, wherein:
the layer stack comprises a lowermost semiconductor layer;
each of the first implanted regions has a first implanted dose and each of the second implanted regions has a second implanted dose; and
the first implanted regions and the second implanted regions are formed such that at least in a portion of the layer stack, at least one of the first implanted dose and the second implanted dose increases towards the lowermost semiconductor layer over the portion of the layer stack.

7. The method of claim 6, wherein the portion of the layer stack includes at least 70% of the layers of the layer stack.

8. The method of claim 7, wherein a maximum of the at least one of the first implanted dose and the second implanted dose in the portion of the layer stack is at least 30% higher than a minimum of the first implanted dose in the portion of the layer stack.

9. The method of claim 6, wherein the at least one of the first implanted dose and the second implanted dose steadily increases towards the lowermost semiconductor layer.

10. The method of claim 6, wherein the at least one of the first implanted dose and the second implanted dose increases stepwise towards the lowermost semiconductor layer.

11. The method of claim 6, wherein the at least one of the first implanted dose and the second implanted dose increases towards the lowermost semiconductor layer such that the at least one of the first implanted dose and the second implanted dose in a lowermost layer of the portion of the layer stack is more than 30% higher than the at least one of the first implanted dose and the second implanted dose in an uppermost lowermost layer of the portion of the layer stack.

12. The method of claim 6, wherein the at least one of the first implanted dose and the second implanted dose increases towards the lowermost semiconductor layer such that an overall dose of the at least one of the first implanted dose and the second implanted dose in three adjacent lowermost layers of the portion of the layer stack is more than 30% higher than an overall dose of the at least one of the first implanted dose and the second implanted dose in three adjacent uppermost layers of the portion of the layer stack.

13. The method of claim 12, wherein the portion of the layer stack comprises the entire layer stack.

14. The method of claim 6, wherein in each of the semiconductor layers of the portion of the layer stack, the first implanted dose substantially equals the second implanted dose.

15. The method of claim 1, wherein:
implanting the first type dopant atoms in each of the semiconductor layers comprises at least two implantation steps at different implantation energies; and
implanting the second type dopant atoms in each of the semiconductor layers comprises at least two implantation steps at different implantation energies.

16. The method of claim 15, wherein the at least two implantation steps comprise exactly two implantation steps.

17. The method of claim 1, wherein the number of semiconductor layers in the layer stack is selected from between 17 and 21.

18. The method of claim 1, wherein forming the layer stack comprises forming the layer stack on top of a carrier.

19. The method of claim 18, wherein the carrier comprises a semiconductor substrate and a semiconductor layer formed on the semiconductor substrate.

20. The method of claim 1, further comprising:
forming a further semiconductor layer on top of the layer stack; and
forming a plurality of transistor cells at least partially integrated in the further semiconductor layer.

21. The method of claim 20, wherein:
forming the plurality of transistor cells comprises an annealing process; and
the annealing process for forming the plurality of transistor cells and the annealing process for forming the superjunction region is the same annealing process.

22. The method of claim 1, wherein the first implanted regions and the second implanted regions are formed to be spaced apart in a first lateral direction of the layer stack and to be elongated in a second lateral direction perpendicular to the first lateral direction.

23. The method of claim 1, wherein the semiconductor layers comprise monocrystalline silicon.

24. A superjunction device, comprising:
a superjunction region comprising a plurality of first regions of a first doping type and a plurality of second regions of a second doping type complementary to the first doping type in a layer stack comprising a plurality of semiconductor layers formed one above the other to form a layer stack,
wherein a pitch of the superjunction region is selected from between 3 micrometers and 5 micrometers, and
wherein each of the semiconductor layers has a thickness selected from between 1.9 micrometers and 3.5 micrometers.

25. The superjunction device of claim 24, wherein:
the layer stack comprises a lowermost semiconductor layer;
each of the first regions has a first implanted dose and each of the second implanted regions has a second implanted dose in each of the layers of the layer stack; and
at least in a portion of the layer stack, at least one of the first implanted dose and the second implanted dose increases towards the lowermost semiconductor layer over the portion of the layer stack.

26. The superjunction device of claim 24, wherein:
the layer stack comprises a lowermost semiconductor layer;
in the second regions, an ineffective lateral dopant dose of first type dopant atoms increases towards the lowermost semiconductor layer; and
in the first regions, an ineffective lateral dopant dose of second type dopant atoms increases towards the lowermost semiconductor layer.
